(19) United States
(12) Patent Application Publication
(10) Pub. No.: US 2026/0246438 A1
(43) Pub. Date: Aug. 20, 2026

(54) ELECTROMAGNETIC INTERFERENCE FILTER

(71) Applicant: Lite-On Technology Corporation, Taipei (TW)

(72) Inventors: Bo-Ruei CIOU, Taipei (TW); Yao-Ting XIE, Taipei (TW); Yu-Wei LIN, Taipei (TW); Yen-An CHEN, Taipei (TW); Chen CHEN, Taipei (TW)

(21) Appl. No.: 19/288,395

(22) Filed: Aug. 1, 2025

Related U.S. Application Data
(60) Provisional application No. 63/760,140, filed on Feb. 19, 2025.

(30) Foreign Application Priority Data
Jun. 13, 2025 (TW) 114122325

(51) Int. Cl. H03H 1/02; H01F 3/02; H01F 3/12; H01F 27/38; H01F 3/10; H03H 1/00

(52) U.S. Cl. CPC H03H 1/02; H01F 3/02; H01F 3/12; H01F 27/385; H01F 2003/106; H03H 2001/0035; H03H 2250/00

(57) ABSTRACT

An electromagnetic interference (EMI) filter includes a first magnetic core, a first choke coil, a second choke coil and a second magnetic core. The first magnetic core has an annular portion and a hollow portion passing through the annular portion. The first choke coil is wound around a first portion of the annular portion, and the second choke coil is wound around a second portion of the annular portion. The first portion is opposite to the second portion. The second magnetic core is arranged in the hollow portion, and the annular portion has at least one recessed portion connected to the second magnetic core.

### CROSS REFERENCE TO RELATED APPLICATIONS

This application claims the benefits of U.S. provisional application Serial No. 63/760,140, filed February 19, 2025 and Taiwan application Serial No. 114122325, filed June 13, 2025, the subject matters of which are incorporated herein by reference.

### BACKGROUND OF THE INVENTION

### Field of the Invention

The invention relates in general to a filter, and more particularly to an electromagnetic interference filter for suppressing common-mode interference and differential-mode interference.

### Description of the Related Art

Conventional electromagnetic interference (EMI) filters usually employ common-mode (CM) inductors or differential-mode (DM) inductors to suppress common-mode interference and differential-mode interference. In addition, there are some integrated filters, such as using multilayer foils, EMI filters and boost inductors to suppress noise currents.

To decrease electromagnetic signal interference and ensure the proper operation of household appliances, common-mode (CM) inductors and differential-mode (DM) inductors are usually installed inside small electronic devices to suppress common-mode interference and differential-mode interference, and prevent the electronic device from emitting EMI signals into the surrounding environment. However, during the operation of the electronic device, reducing common-mode interference and differential-mode interference through common-mode inductors and differential-mode inductors would complicate the circuit structure and increase the manufacturing cost of the electronic device.

### SUMMARY OF THE INVENTION

The present invention relates to an EMI filter, which increases the leakage inductance of a common-mode inductor by modifying the structure of a magnetic core to obviate the need for a differential-mode inductor.

According to one aspect of the present invention, an EMI filter is provided, including a first magnetic core, a first choke coil, a second choke coil and a second magnetic core. The first magnetic core has an annular portion and a hollow portion passing through the annular portion, the first choke coil is wound around a first portion of the annular portion, and the second choke coil is wound around a second portion of the annular portion. The first portion is opposite to the second portion. The second magnetic core is arranged in the hollow portion, and the annular portion has at least one recessed portion connected to the second magnetic core.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a filter circuit having a common-mode inductor and a capacitor.

FIG. 2 is a schematic diagram of a magnetic field of an EMI filter with a second magnetic core.

FIG. 3 and FIG. 4 are respectively a three-dimensional diagram of an EMI filter according to an embodiment of the present invention and a schematic exploded diagram of a magnetic core thereof.

FIG. 5 and FIG. 6 are schematic diagrams of magnetic cores of EMI filters according to different embodiments of the present invention.

### DETAILED DESCRIPTION OF THE INVENTION

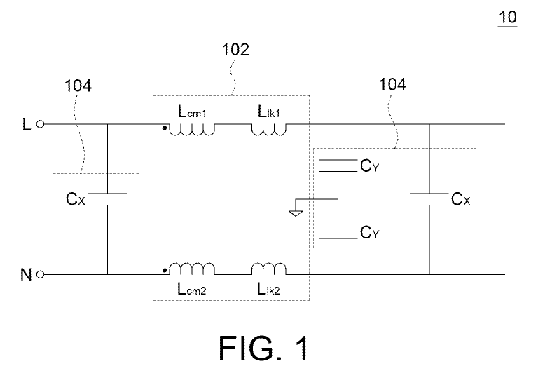

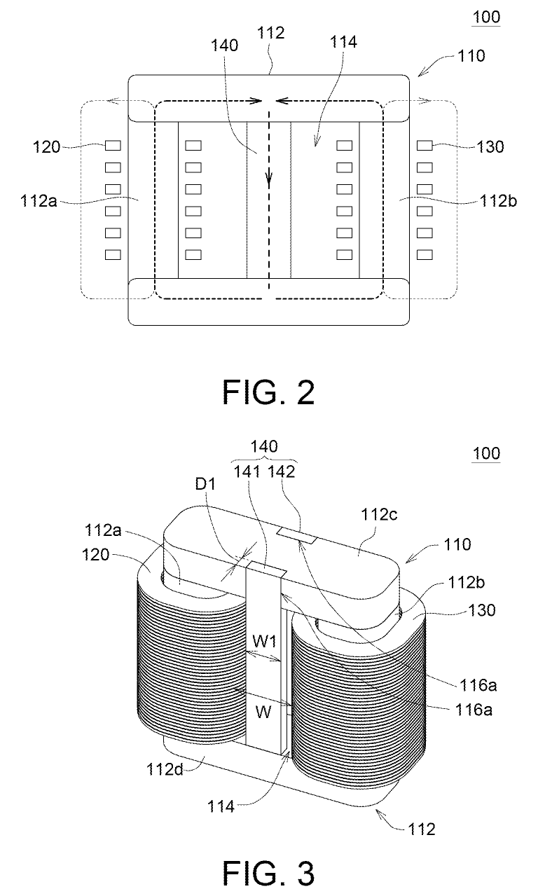

Referring to FIGS. 1 and 2, FIG. 1 is a schematic diagram of a filter circuit 10 having a common-mode inductor 102 and capacitors 104, and FIG. 2 is a schematic diagram of a magnetic field of an EMI filter 100 with a second magnetic core 140. The filter circuit 10 includes a common-mode inductor 102 and capacitors 104 connected in parallel, and further connected with two power lines L and N. The common-mode inductor 102 provides a high-impedance path for high-frequency signals to effectively reduce high-frequency noise passing through the common-mode inductor 102. In addition, the capacitors 104 provide a low-impedance path for high-frequency signals to bypass high-frequency noise from the main signal path and guide it to the ground, ensuring that only the required low-frequency signal passes through the filter circuit 10, thereby improving the effectiveness of the common-mode inductor 102. In this embodiment, the leakage inductance of the common-mode inductor 102 is increased by modifying the structure of the magnetic core to obviate the need for the differential-mode inductor. In FIG. 1, L_{cm1} and L_{cm2} represent the inductance of the common-mode inductor 102, Lₗₖ₁ and Lₗₖ₂ represent the leakage inductance of the common-mode inductor 102, and Cx and Cy represent the impedance of the capacitors 104.

Referring to FIG. 2, the EMI filter 100 includes a first magnetic core 110, a first choke coil 120, a second choke coil 130, and a second magnetic core 140. The first magnetic core 110 has an annular portion 112 and a hollow portion 114 passing through the annular portion 112. The first choke coil 120 is wound around a first portion 112a of the annular portion 112, and the second choke coil 130 is wound around a second portion 112b of the annular portion 112. The first portion 112a is opposite to the second portion 112b. The first portion 112a and the second portion 112b may be columnar structures.

In this embodiment, the first magnetic core 110 and the first choke coil 120 and the second choke coil 130 wound thereon form the common-mode inductor 102 shown in FIG. 1 to filter out common-mode interference. In addition, the second magnetic core 140 is disposed in the hollow portion 114 of the first magnetic core 110, and the second magnetic core 140 forms a magnetic bridge to connect the opposite ends of the annular portion 112, thereby increasing the leakage inductance of the first choke coil 120 and the second choke coil 130 being coupled. As shown in FIG. 1, the leakage inductances Lₗₖ₁ and Lₗₖ₂ can replace the differential-mode inductor to filter out differential-mode interference.

In detail, the first magnetic core 110 is, for example, a ring frame or a quadrilateral frame. The first choke coil 120 is wound around the first portion 112a of the first magnetic core 110, and the second choke coil 130 is wound around the second portion 112b of the first magnetic core 110. The winding directions of the first choke coil 120 and the second choke coil 130 are opposite. The first choke coil 120 and the second choke coil 130 can be made by flat copper wire to achieve electromagnetic characteristics of large current and low resistance. The EMI filter is suitable for suppressing common-mode interference and differential-mode interference before AC-DC converters, for example. Since the differential-mode interference signal currents in the first choke coil 120 and the second choke coil 130 each generate a part of magnetic flux, portions of the magnetic flux cancel each other out due to opposite directions, and some of the magnetic flux leak into the air (as shown by the dotted lines on the left and right sides), and the second magnetic core 140 can capture and utilize the leaked magnetic flux, so as to increase the leakage inductance, thereby increasing the differential-mode inductance value. Since the impedance of the differential-mode interference signal current increases, the differential-mode interference is reduced.

In addition, the second magnetic core 140 is arranged in the hollow portion 114 of the first magnetic core 110, so that the magnetic permeability of the hollow portion 114 of the first magnetic core 110 is increased, thereby causing the magnetic field lines to be distributed to the area outside the first magnetic core 110. Since the leakage inductance in the first choke coil 120 and the second choke coil 130 is increased, the differential-mode interference signal current is filtered out accordingly.

In addition, the magnetic fields induced by the differential-mode interference signal currents in the first choke coil 120 and the second choke coil 130 in the annular first magnetic core 110 are equal in magnitude but opposite in direction, so as to cancel each other out. In addition, the common-mode interference signal currents in the first choke coil 120 and the second choke coil 130 are equal in magnitude and have same phase, thus inducing a magnetic field with the same phase superposition in the first magnetic core 110. Since the common-mode interference signal current is subjected to a larger AC impedance and unable to pass through the EMI filter 100, the common-mode interference is reduced.

The EMI filter 100 of the present embodiment has a high impedance characteristic similar to that of a general common-mode inductor, while also functioning as a differential-mode inductor. Thus, the EMI filter 100 of the present embodiment has the functions of both common-mode and differential-mode inductors. The filter circuit of FIG. 1 does not need to additionally set up a differential-mode inductor to reduce differential-mode interference, thereby eliminating the cost of providing a differential-mode inductor and the space occupied by the differential-mode inductor.

In one embodiment, the material of the first magnetic core 110 and the second magnetic core 140 may include one or more of amorphous magnetic materials, manganese zinc ferrite, nickel zinc ferrite and iron powder, and common magnetic core materials are Fe-Si-Al (sendust cores), Fe-Ni (high flux cores), Fe-Ni-Mo (MPP cores), Fe-Si (mega flux cores), and iron powder cores. In addition, the first magnetic core 110 and the second magnetic core 140 with appropriate magnetic permeability are selected, for example, the first magnetic core 110 with high magnetic permeability and the second magnetic core 140 with relatively low magnetic permeability are used, the magnetic permeability of the first magnetic core 110 may be 10000 μi, and the magnetic permeability of the second magnetic core 140 may be less than half of the magnetic permeability of the first magnetic core 110.

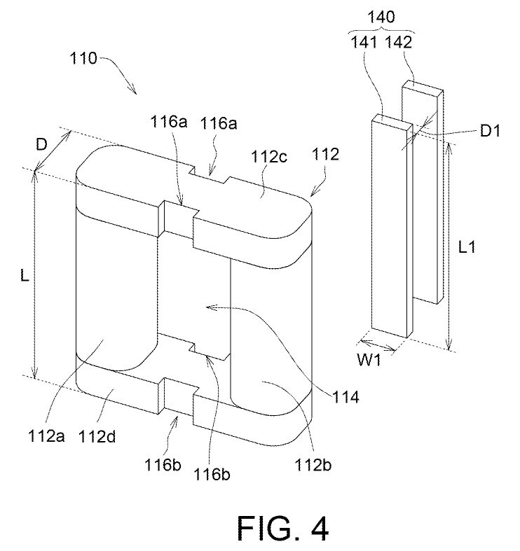

In addition, the shape and relative position of the first magnetic core 110 and the second magnetic core 140, as well as the winding conditions of the first choke coil 120 and the second choke coil 130 are adjusted so that the distribution of the magnetic flux lines in the first magnetic core 110 and the second magnetic core 140 remains balanced, so as to filter out the common-mode interference signal current and the differential-mode interference signal current, and improve the signal-to-noise ratio of the current in the current loop. For example, in FIG. 3, in order to facilitate the fixing of the second magnetic core 140, the upper end 112c of the annular portion 112 of the first magnetic core 110 has two recessed portions 116a connected to the second magnetic core 140, and the lower end 112d of the annular portion 112 is only connected to the second magnetic core 140 but no recessed portion is provided. The second magnetic core 140 includes but is not limited to, two elongated magnetic sheets 141 and 142, and the two elongated magnetic sheets 141 and 142 can be fixed in the two recessed portions 116a through adhesive.

In addition, in FIG. 4, in order to facilitate the fixing of the second magnetic core 140, the lower end 112d of the annular portion 112 of the first magnetic core 110 also has two recessed portions 116b connected to the second magnetic core 140. The second magnetic core 140 may include two elongated magnetic sheets 141 and 142, which can be fixed in the two recessed portions 116b by adhesive.

Furthermore, by adjusting the size of the second magnetic core 140, the leakage inductance can be flexibly controlled, thereby avoiding the first magnetic core 110 entering a saturated state and affecting the performance of the EMI filter 100 in filtering out common-mode interference signals. For example, in FIG. 3 and FIG. 4, the width W1 of the second magnetic core 140 is approximately equal to or less than the minimum spacing W between the adjacent two outer surfaces of the first choke coil 120 and the second choke coil 130, and the length L1 of the second magnetic core 140 is approximately equal to or less than the length L of the first magnetic core 110 in the vertical (length) direction, and the thickness D1 of the second magnetic core 140 is approximately equal to or less than 1/6 of the thickness D of the first magnetic core 110 in the horizontal direction, so as to reduce the space occupied by the second magnetic core 140. In one embodiment, the length L1 of the second magnetic core 140 may be but is not limited to between 16.4 mm and 18.6 mm, the width W1 of the second magnetic core 140 may be but is not limited to between 3 mm and 4 mm, and the thickness D1 of the second magnetic core 140 may be but is not limited to between 1 mm and 1.8 mm.

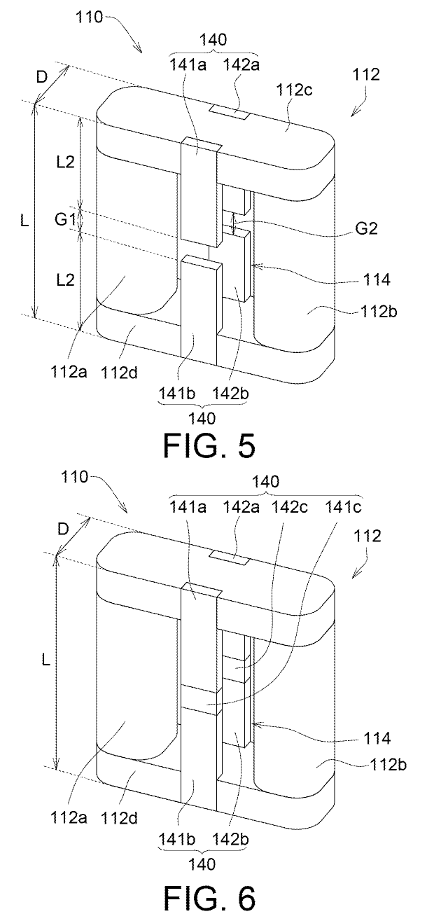

Referring to FIG. 5 and FIG. 6, schematic diagrams of magnetic cores of EMI filters according to different embodiments of the present invention are illustrated. For the convenience of explanation, FIG. 5 and FIG. 6 omit the first choke coil 120 and the second choke coil 130. In FIG. 5, in order to control the magnitude of the leakage inductance, a second magnetic core 140 with a lower magnetic permeability than the first magnetic core 110 is selected. The second magnetic core 140 includes a first magnetic conductive member 141a and a second magnetic conductive member 141b. The first magnetic conductive member 141a and the second magnetic conductive member 141b are separated by a first spacing G1. In one embodiment, the first magnetic conductive member 141a can be fixed to the first recessed portion 116a (as shown in FIG. 4) of the upper end 112c of the annular portion 112 through adhesive, and the second magnetic conductive member 141b is fixed to the second recessed portion 116b (as shown in FIG. 4) of the lower end 112d of the annular portion 112. The length L2 of the first magnetic conductive member 141a and the second magnetic conductive member 141b is approximately less than half of the length L of the first magnetic core 110 in the vertical direction, so as to form a magnetic gap between the first magnetic conductive member 141a and the second magnetic conductive member 141b.

In addition, in FIG. 5, in order to control the magnitude of the leakage inductance, the second magnetic core 140 may also include a third magnetic conductive member 142a and a fourth magnetic conductive member 142b. The third magnetic conductive member 142a and the fourth magnetic conductive member 142b are separated by a second spacing G2. In one embodiment, the third magnetic conductive member 142a can be fixed to the third recessed portion 116a (as shown in FIG. 4 ) of the upper end 112c of the annular portion 112 by means of adhesive, fastening, or snapping, and the fourth magnetic conductive member 142b is fixed to the fourth recessed portion 116b (as shown in FIG. 4 ) of the lower end 112d of the annular portion 112, and the length L2 of the third magnetic conductive member 142a and the fourth magnetic conductive member 142b is approximately less than half of the length L of the first magnetic core 110 in the vertical direction, so as to form a magnetic gap between the third magnetic conductive member 142a and the fourth magnetic conductive member 142b. The magnetic permeability of the first magnetic core 110 may be 10000 μi, and each of magnetic permeabilities of the first magnetic conductive member 141a, the second magnetic conductive member 141b, the third magnetic conductive member 142a, and the fourth magnetic conductive member 142b may be less than half of the magnetic permeability of the first magnetic core 110, for example, between 3300 and 5000 μi.

Referring to FIG. 6, the second magnetic core 140 of this embodiment is different from the above embodiment in that: in order to control the magnitude of the leakage inductance, the second magnetic core 140 also includes a fifth magnetic conductive member 141c and a sixth magnetic conductive member 142c, wherein the fifth magnetic conductive member 141c is disposed between the first magnetic conductive member 141a and the second magnetic conductive member 141b, and the fifth magnetic conductive member 141c is respectively connected to the first magnetic conductive member 141a and the second magnetic conductive member 141b in the vertical direction (i.e., the length direction of the first magnetic core 110). The magnetic permeability of the fifth magnetic conductive member 141c is less than the magnetic permeability of the first magnetic conductive member 141a and the second magnetic conductive member 141b. The magnetic permeability of the fifth magnetic conductive member 141c may be about 60μi, but the invention is not limited thereto.

In addition, the sixth magnetic conductive member 142c is disposed between the third magnetic conductive member 142a and the fourth magnetic conductive member 142b, and the sixth magnetic conductive member 142c is respectively connected to the third magnetic conductive member 142a and the fourth magnetic conductive member 142b in the vertical direction (i.e., the length direction of the first magnetic core 110). The magnetic permeability of the sixth magnetic conductive member 142c is less than the magnetic permeability of the third magnetic conductive member 142a and the fourth magnetic conductive member 142b. The magnetic permeability of the sixth magnetic conductive member 142c may be about 60μi, but the invention is not limited thereto. For example, the magnetic permeability of the fifth magnetic conductive member 141c and the sixth magnetic conductive member 142c is less than 10% of the magnetic permeability of the first magnetic core 110, preferably, less than 1%, that is, the magnetic permeability of the fifth magnetic conductive member 141c and the sixth magnetic conductive member 142c is less than the overall magnetic permeability of the second magnetic core 140.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electromagnetic interference (EMI) filter, comprising:
a first magnetic core having an annular portion and a hollow portion passing through the annular portion;
a first choke coil wound around a first portion of the annular portion;
a second choke coil wound around a second portion of the annular portion, wherein the first portion is opposite to the second portion; and
a second magnetic core disposed in the hollow portion, and the annular portion has at least one recessed portion connected to the second magnetic core.

2. The EMI filter of claim 1, wherein the first magnetic core is an annular frame or a quadrilateral frame.

3. The EMI filter of claim 1, wherein a magnetic permeability of the first magnetic core is greater than a magnetic permeability of the second magnetic core.

4. The EMI filter of claim 1, wherein the second magnetic core includes at least one elongated magnetic sheet.

5. The EMI filter of claim 4, wherein the at least one elongated magnetic sheet is fixed in the at least one recessed portion by adhesive.

6. The EMI filter of claim 1, wherein a length of the second magnetic core is equal to or less than a length of the first magnetic core.

7. The EMI filter of claim 1, wherein a thickness of the second magnetic core is equal to or less than 1/6 of a thickness of the first magnetic core.

8. The EMI filter of claim 1, wherein the second magnetic core includes a first magnetic conductive member and a second magnetic conductive member, the first magnetic conductive member and the second magnetic conductive member are separated by a first spacing, wherein the first magnetic conductive member is fixed in a first recessed portion of the annular portion, and the second magnetic conductive member is fixed in a second recessed portion of the annular portion.

9. The EMI filter of claim 8, wherein each length of the first magnetic conductive member and the second magnetic conductive member is less than half a length of the first magnetic core.

10. The EMI filter of claim 8, wherein the second magnetic core further includes a third magnetic conductive member and a fourth magnetic conductive member, the third magnetic conductive member and the fourth magnetic conductive member are separated by a second spacing, wherein the third magnetic conductive member is fixed in a third recessed portion of the annular portion, and the fourth magnetic conductive member is fixed in a fourth recessed portion of the annular portion.

11. The EMI filter of claim 10, wherein each length of the third magnetic conductive member and the fourth magnetic conductive member is less than half a length of the first magnetic core.

12. The EMI filter of claim 10, wherein the second magnetic core further includes a fifth magnetic conductive member, wherein the fifth magnetic conductive member is disposed between the first magnetic conductive member and the second magnetic conductive member, and the fifth magnetic conductive member is respectively connected to the first magnetic conductive member and the second magnetic conductive member in a length direction of the first magnetic core.

13. The EMI filter of claim 12, wherein a magnetic permeability of the fifth magnetic conductive member is less than each magnetic permeability of the first magnetic conductive member and the second magnetic conductive member.

14. The EMI filter of claim 12, wherein the second magnetic core further includes a sixth magnetic conductive member, the sixth magnetic conductive member is disposed between the third magnetic conductive member and the fourth magnetic conductive member, and the sixth magnetic conductive member is respectively connected to the third magnetic conductive member and the fourth magnetic conductive member in the length direction.

15. The EMI filter of claim 14, wherein a magnetic permeability of the sixth magnetic conductive member is less than each magnetic permeability of the third magnetic conductive member and the fourth magnetic conductive member.
